(19) United States
(12) Patent Application Publication
(10) Pub. No.: US 2025/0301816 A1
(43) Pub. Date: Sep. 25, 2025

(54) SINGLE-PHOTON AVALANCHE DIODE

(71) Applicant: ams-OSRAM AG, Premstaetten (AT)

(72) Inventor: Georg ROEHRER, Lebring-Sankt Margarethen (AT)

(21) Appl. No.: 18/860,009

(22) PCT Filed: May 3, 2023
(86) PCT No.: PCT/EP2023/061658

§ 371 Date: Oct. 25, 2024

(30) Foreign Application Priority Data
May 6, 2022 (GB) 2206670.8

(51) Int. Cl. H10F 77/14; H04N 25/78; H10F 30/225; H10F 39/10; H10F 77/00

(52) U.S. Cl. CPC H10F 77/146; H04N 25/78; H10F 30/225; H10F 39/107; H10F 77/933

(57) ABSTRACT

A single-photon avalanche diode, SPAD, includes a first well-region formed in a substrate and a second well-region formed on the substrate and extending at least partway around the first well-region. The SPAD further includes at least one contact formed over the second well-region and a deep well-region extending non-uniformly between the first well-region and the second well-region. The first well-region is formed at a junction defining an avalanche region. The second well-region and the deep well-region are configured to provide a conductive path between the avalanche region and the at least one contact.

### RELATED APPLICATIONS

This patent application is a US National Stage application, filed under 35 U.S.C. § 371, of International Application PCT/EP2023/061658, filed on May 3, 2023, and claims priority under from United Kingdom Patent Application GB 2206670.8, filed May 6, 2022, the contents of the above applications are hereby incorporated by reference.

### TECHNICAL FIELD OF THE DISCLOSURE

The present disclosure is in the field of single-photon avalanche diodes (SPADs), and relates in particular to SPADs suitable for use with high excess bias voltages relative to an operating voltage of associated read-out electronics.

### BACKGROUND

A Single Photon Avalanche Diode (SPAD) is a solid-state photodetector based around a semiconductor p-n junction.

A conventional photodiode may operate with a relatively low reverse bias voltage, wherein a leakage current may change linearly with absorption of incident photons due to an internal photoelectric effect. In contrast, a SPAD may be configured to be biased above its breakdown voltage. The reverse bias may be sufficiently high such that photons incident on the SPAD may cause impact ionization triggering generation of an avalanche current.

That is, a photo-generated carrier may be accelerated by an electric field in the SPAD due to the relatively high reverse bias voltage, wherein the photo-generated carrier may trigger an avalanche current due to an impact ionization mechanism. As such, a SPAD may be capable of detecting incidence of individual photons. A SPAD biased well above its reverse-bias breakdown voltage may be known in the art as operating within a “Geiger-mode” region.

Typically, after a SPAD has been triggered for a sufficient time, the avalanche current may be ‘quenched’ by lowering the bias down to the breakdown voltage or lower. Circuits for quenching the avalanche current may be either passive, e.g. as simple as a single resistor in series with the SPAD, or active, e.g. comprising additional circuitry such as one or more transistors for actively controlling the bias voltage.

After quenching, the SPAD may be ‘reset’ in order to re-enable detection of incident photons. That is, after the avalanche breakdown is stopped, the SPAD may be recharged to its relatively high reverse bias voltage, e.g. significantly above a breakdown voltage of the SPAD.

In use, a SPAD or an array of SPADs may be coupled to read-out circuitry for determining whether and when the SPAD or SPADs have been triggered and/or for counting triggering events.

However, a maximum usable excess bias voltage of a SPAD with integrated read-out electronics may be limited by a maximum voltage supported by low-voltage transistors used to implement the read-out circuitry. Similarly, the maximum usable excess bias voltage of the SPAD may be limited by a maximum voltage supported by transistors or circuitry used to implement quenching.

If the SPAD excess bias voltage is too high, the integrated read-out electronics and/or quench circuit may be prone to damage.

However, a high excess bias voltage may improve a performance of a SPAD. For example, a high excess bias voltage may improve a Photon Detection Efficiency (PDE) and reduce jitter, resulting in an overall improved performance of a device using the SPAD.

It is therefore desirable to provide a SPAD that provides the beneficial characteristics of a SPAD operating with an excess bias voltage that can exceed voltage specifications of relatively low-voltage transistors implemented in read-out and/or quenching circuitry.

At least one embodiment of at least one aspect of the present disclosure relates to obviating or at least mitigating at least one of the above identified shortcomings of the prior art.

### SUMMARY

The present disclosure is in the field of SPADs, and relates in particular to SPADs suitable for use with high excess bias voltages relative to an operating voltage of associated read-out electronics.

According to a first aspect of the disclosure, there is provided a single-photon avalanche diode (SPAD) comprising: a first well-region formed in a substrate; a second well-region formed on the substrate and extending at least partway around the first well-region; at least one contact formed over the second well-region; and a deep well region extending non-uniformly between the first well-region and the second well region, wherein the first well-region is formed at a junction defining an avalanche region, and wherein the second well-region and the deep well-region are configured to provide a conductive path between the avalanche region and the at least one contact.

By having the deep well-region extending non-uniformly between the first well-region and the second well-region, a resistance of the conductive path between the first well-region and the at least one contact may be increased relative to a prior art SPAD where the deep well-region may extend uniformly between the first well-region and the second well-region.

As such, the SPAD itself is effectively implemented with an internal quenching resistor, e.g. the conductive path provides sufficient resistance to act as a quenching resistor.

In some examples, an additional external quenching resistor, or transistor, may also be used with the SPAD. Due to the effective internal quenching resistance of the conductive path, a voltage seen by a transistor used for quenching may be reduced.

Furthermore, requirements for any read-out electronics may also be reduced according to the resistive voltage divider formed by the effective internal quenching resistor and any external quenching resistor or transistor.

That is, the internal quenching resistor may enable the SPAD to be operated at an excess bias voltage exceeding a maximum operating voltage for low-voltage transistors that may be used to implement the read-out electronics. This enables the SPAD to be operated with a higher excess bias voltage, thereby improving photon detection efficiency and timing jitter, and overall product performance.

Furthermore, in an array of SPADs it may sometimes be beneficial to disable one or more SPADs. Example reasons for this can be that some SPADs may exhibit a very high dark count rate or that in a certain application mode not all SPADs in the array are required. With a prior art SPAD, this may be implemented by connecting an anode of the SPAD to be disabled with a switch to VDD and by an additional switch in the path of the quenching transistor to avoid a permanent current flowing from VDD to VSS.

If the same is done with a SPAD according to the present disclosure, and the excess bias voltage exceeds VDD, the SPAD may not be not fully disabled but may operate with an excess bias voltage reduced by VDD. There is no problem with quenching because for small excess bias voltages the internal quenching resistor is sufficient for proper quenching. There will also be no signal detected since the input of the buffer is connected to VDD.

It will be understood that extending non-uniformly may include extending with non-uniformities in a doping density and/or extending with non-uniformities in a distribution e.g. not laterally extending continuously all around the first well, as will be described in more detail below. In contrast, prior art SPADs may be implemented wherein a deep well-region may extend uniformly, e.g. with a uniform doping density between the first well-region and the second well-region and extending continuously all around the first well.

The junction defining the avalanche region may be a pn junction. As described in more detail with reference to the embodiments below, in some examples the pn junction may be formed between the first-well region and an implant region formed on the first well region. In some examples the pn junction may be formed between the first-well region and the deep well region. In some examples the pn junction may be formed between the first-well region and a further well region or implant region formed in the deep well region.

When viewed in a direction orthogonal to a surface of the substrate, the deep well-region may extend only partway around the first well-region.

By extending only partway around the first well-region, the resistance of the conductive path between the first well-region and the at least one contact may be increased relative to a prior art SPAD wherein the deep well-region may extend uniformly between the first well-region and the second well-region. Furthermore, in particular embodiments, the deep well-region may only extend towards one or more portions of the second well, without extending below a contact formed in the second well. As such, a path length of the conductive path may be relatively long, thereby increasing an overall resistance of the conductive path.

A doping density of the deep well-region between the first well-region and the second well-region may be non-uniform.

For example, a doping density of the deep well-region between the first well region and the second well-region may be lower than a doping density of the deep well region directly below the first well-region and/or the second well-region. By having a region of relatively lower doping density, an overall resistance of the conductive path between the first well-region and the second well region may be increased.

A region of the deep well-region between the first well-region and the second well-region may have a lower doping concentration than regions of the deep well region directly below the first well-region and the second well-region.

For example, forming the deep well region may comprise forming a first portion of the deep well-region and a second portion of the deep well-region separated by a gap, wherein a lateral spread and/or thermal diffusion of the deep well-region causes the conductive path to extend across the gap, but with a lower doping concentration within the gap.

A size of the gap may be selected to define a resistance of the conductive path.

The conductive path may be an indirect conductive path.

That is, the conductive path may not be a straight line between the first well region and the at least one contact.

The deep well-region may not extend below the at least one contact

A length of the path may be extended, because the path may have to extend along, e.g. laterally in a direction substantially parallel to a surface of the substrate, to the at least one contact.

The second well-region and the deep well-region may not be configured to provide a direct conductive path between the avalanche region and the at least one contact.

That is, the conductive path may not be a straight line between the first well region and the at least one contact.

The conductive path may not be the shortest path between the first well-region and the at least one contact. This may result in a longer path between the first well-region and the at least one contact, thereby increasing an overall resistance of the path.

When viewed in a cross section extending through a center of the SPAD and through the at least one contact, the SPAD may not be symmetrical.

For example, when viewed in the cross section, the deep well may extend only in a first direction toward the second well-region.

The SPAD may comprise a plurality of conductive paths, each path extending in a different direction at least partway around the first well-region.

For example, if the conductive path extends from a first side of the first well region to the second well-region, and the at least one contact is disposed at another side or an opposite side of the first well-region, then the conductive paths may extend in both directions, e.g. clockwise and anticlockwise, around the first well region.

The SPAD may comprise an implant region formed on the first well-region to define the avalanche region of the SPAD. At least one further contact may be formed over the implant region.

In some examples, the at least one contact may provide a cathode and a conductivity type of the second well-region may be n-type, and the at least one further contact may provide an anode and the conductivity type of the implant region may be p-type.

In some examples, the at least one contact may provide an anode and a conductivity type of the second well-region may be p-type, and the at least one further contact may provide a cathode and the conductivity type of the implant region may be n-type.

The SPAD may comprise a guard ring provided by a lightly-doped lateral region extending between the first well-region and the second well-region. The guard ring may extend completely around the first well-region.

When viewed in a direction orthogonal to a surface of the substrate, the first well-region may be disposed between the at least one contact and a location where the deep well-region extends to the second well-region.

According to a second aspect of the disclosure, there is provided an array of SPADs comprising: a plurality of first well-regions formed in a substrate; a second well region formed on the substrate and extending at least partway around and/or between the plurality of first well-regions; at least one contact formed over the second well region; and a deep well-region extending non-uniformly between each first well-region and the second well-region, wherein each first well-region is formed at a junction defining a respective avalanche region, and wherein the second well-region and the deep well-region are configured to provide a conductive path between each avalanche region and the at least one contact.

According to a third aspect of the disclosure, there is provided a SPAD pixel read-out circuit comprising: a SPAD according to the first aspect; and an output buffer coupled to an anode of the SPAD; wherein the SPAD is configured such that, in use, an excess bias voltage level across an avalanche region of the SPAD exceeds a voltage level at the anode and a voltage level of a power supply (VDD) the output buffer.

According to a fourth aspect of the disclosure, there is provided a method of manufacturing a SPAD, the method comprising: forming a deep well-region in a substrate; forming a first well-region in the deep well-region and forming a second well-region extending at least partway around the first well-region; and forming at least one contact over the second well-region, wherein the deep well-region is formed to extend non-uniformly between the first well-region and the second well-region, wherein the first well-region is formed at a junction defining an avalanche region, and wherein the second well-region and the deep well-region are formed to provide a conductive path between the avalanche region and the at least one contact.

By having the deep well-region extending non-uniformly between the first well-region and the second well-region, a resistance of the conductive path between the first well-region and the at least one contact may be increased relative to a prior art SPAD wherein the deep well-region may extend uniformly between the first well-region and the second well-region.

Forming the deep well region may comprise forming a first portion of the deep well-region and a second portion of the deep well-region separated by a gap, wherein a lateral spread and/or thermal diffusion of the deep well-region causes the conductive path to extend across the gap.

When viewed the direction orthogonal to a surface of the substrate, the first portion of the deep well-region may extend under the first well-region and the second portion of the deep well-region may extend under the second well-region.

The deep well-region may be formed such that, when viewed in the direction orthogonal to a surface of the substrate, the deep well-region extends only partway around the first well-region such that the deep well-region does not extend below the at least one contact.

The above summary is intended to be merely exemplary and non-limiting. The disclosure includes one or more corresponding aspects, embodiments or features in isolation or in various combinations whether or not specifically stated (including claimed) in that combination or in isolation. It should be understood that features defined above in accordance with any aspect of the present disclosure or below relating to any specific embodiment of the disclosure may be utilized, either alone or in combination with any other defined feature, in any other aspect or embodiment or to form a further aspect or embodiment of the disclosure.

### BRIEF DESCRIPTION OF THE DRAWINGS

These and other aspects of the present disclosure will now be described, by way of example only, with reference to the accompanying drawings, wherein:

FIG. 1 depicts a schematic of a prior art SPAD pixel read-out circuit;

FIG. 2 depicts a cross-sectional view and a plan view of a prior art SPAD, as may be implemented in the pixel of FIG. 1;

FIG. 3 depicts a SPAD-based pixel according to an embodiment of the disclosure;

FIG. 4 a cross-sectional view and a plan view of a SPAD according to an embodiment of the disclosure;

FIG. 5 a cross-sectional view and a plan view of a SPAD according to a further embodiment of the disclosure;

FIG. 6 a cross-sectional view and a plan view of a SPAD according to a further embodiment of the disclosure;

FIG. 7 a cross-sectional view and a plan view of a SPAD according to a further embodiment of the disclosure;

FIG. 8a a plan view of a SPAD array according to an embodiment of the disclosure;

FIG. 8b a plan view of a SPAD array according to a further embodiment of the disclosure; and

FIG. 9 depicts partial cross-sections of further configurations of SPADs, which may be combined with the concepts disclosed in FIGS. 4 to 8 to implement further embodiments of the disclosure.

### DETAILED DESCRIPTION

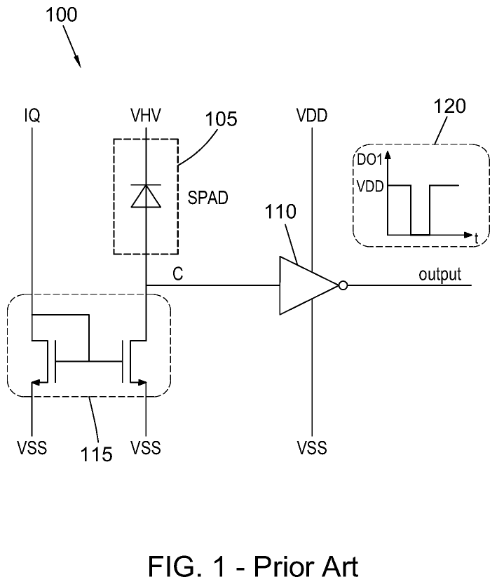

FIG. 1 depicts a schematic of a prior art SPAD pixel read-out circuit 100. The circuit 100 comprises a SPAD 105, where a cathode of the SPAD 105 is coupled to a high voltage reference VHV and an anode of the SPAD 105 is coupled to a buffer 110. The buffer 110 represents read-out circuitry, e.g. a circuit configured to read-out a state of the SPAD.

In an example, the circuit 100 may be an integrated device, wherein the buffer 110 may be fabricated using low-voltage CMOS transistors. The buffer 110 is coupled to a supply voltage VDD. A voltage of the supply rail VDD is lower than a voltage of the high voltage reference VHV. For purpose of example only, the buffer 110 is implemented as an inverter. That is, an output of the buffer 110 represents an inverse of node C, e.g. if a voltage at node C is high, an output of the inverter is low. Node C corresponds to the anode of the SPAD 105

Also depicted is a current mirror 115, configured to mirror a quench current IQ to the SPAD 105. That is, the current mirror 115 implements a passive quenching circuit configured to provide a constant quench current IQ. It will be understood that this is merely an example of a quenching circuit, and other quenching circuits are known in the art.

For example only, a representation of an output 120 from the circuit 100 is also depicted. The buffer 110 may indicate occurrence of avalanche triggering events, e.g. photon strikes, as a drop in an output voltage of the buffer 110

In use, if an excess bias voltage across the SPAD 105 substantially exceeds the supply voltage VDD, then the voltage at node “C” will exceed VDD. As such, electrical overstress to the transistors of the current mirror circuit 115 and to the transistors of the buffer 110 may occur.

That is, a maximum usable excess bias voltage of the SPAD 105 may be limited by a maximum voltage supported by low-voltage transistors used to implement the read-out circuitry and quenching circuitry, e.g. buffer 110 and current mirror 115. If the excess bias voltage of the SPAD 105 is too high, the current mirror circuit 115 and/or the buffer 110 may be prone to damage.

This may limit a performance of such a prior art circuit 100, because a high excess bias voltage may be desirable to improve a performance of the SPAD 105, e.g. to improve a Photon Detection Efficiency (PDE) of the SPAD 105.

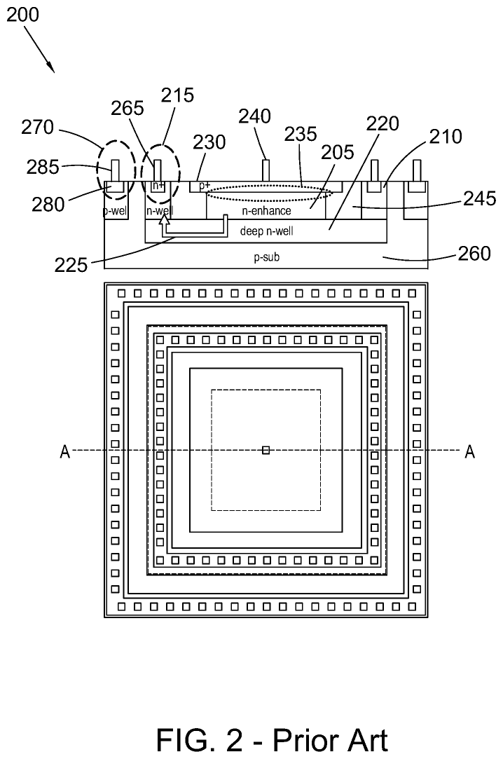

FIG. 2 depicts a plan view of a prior art SPAD 200. FIG. 2 also depicts a cross-sectional view of the SPAD 200 across a line A-A.

The SPAD 200 may be implemented as the SPAD 105 in the SPAD pixel readout circuit 100 of FIG. 1.

The example SPAD 200 is formed on a P-type substrate 260.

The example SPAD comprises a first well-region 205 formed in the substrate 260. In the following example, the first well-region 205 is denoted an “N-enhance region”, e.g. a well heavily doped with n-type impurities.

Also depicted is a second well-region 210 formed in the P-type substrate 260. The second well-region 210 is an N-type well, e.g. formed by diffusion of n-type impurities into the P-type substrate 260.

A plurality of contacts 215 are formed over the second well-region 210. The plurality of contacts 215 comprises an N+ diffused portion, for providing an ohmic contact to a plurality of cathodes 265, where the cathodes 265 may be implemented in a metal layer.

A deep well-region 220 is depicted. The deep well-region 220 is formed below the first well-region 205 and the second well-region 210 in the p-type substrate 260, and extends uniformly between the first well-region 205 and the second well-region 210.

In some embodiments, the deep well-region 220 may extend to a surface of the substrate. In such embodiments, the second well-region 210 is effectively formed by the deep well region, e.g. a portion of the deep well region.

The SPAD 200 also comprises a P+ implant region 230 formed on the first well region 205, to define an avalanche region 235 of the SPAD 200.

That is, the second well-region 210 and the deep well-region 220 are configured to provide a conductive path 225 between the avalanche region 235 and the plurality of contacts 215.

A further contact 240 is formed over the implant region 230 to define an anode of the SPAD 200.

For completeness, further contacts 270 to the p-type substrate 260 are also depicted. A p-well is formed in the p-type substrate 260 and the further contacts 270 are formed from a P+ diffused portion 280, for providing an ohmic contact to a plurality of metal contacts 285.

Also shown in FIG. 2 is a plan view of the SPAD 200. In the plan view it can be seen that the second well-region 210 extends completely around the first well-region 205.

Furthermore, the deep well-region 220 extends uniformly between the first well region 205 and the second well-region 210. That is, the deep well-region 220 extends with a uniform doping density between the first well-region 205 and the second well region 210, and the deep well-region 220 extends laterally in all directions between the first well-region 205 and the second well-region 210.

As such, the second well-region and the deep well-region are configured to provide a very low resistance conductive path 225 between the avalanche region 235, e.g. the first well-region 205, and the plurality of contacts 215.

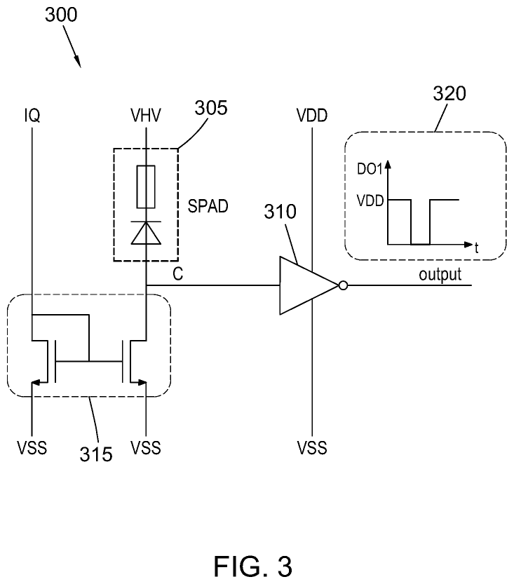

FIG. 3 depicts a SPAD pixel read-out circuit 300 according to an embodiment of the disclosure. The SPAD pixel read-out circuit 300 comprises a SPAD 305. For purposes of illustration, the equivalent circuit of the SPAD 305 is depicted, wherein the SPAD 305 comprises an internal resistor 395 effectively coupled between a cathode of a photosensitive component of the SPAD 305 and a high voltage reference VHV. An anode of the SPAD 305 is coupled to a buffer 310. The buffer 310 represents read-out circuitry, e.g. a circuit configured to read-out a state of the SPAD.

The SPAD pixel read-out circuit 300 is an integrated device, and as such the buffer 310 may be fabricated using low-voltage CMOS transistors. The buffer 310 is coupled to a supply voltage VDD. A voltage of the supply rail VDD is lower than a voltage of the high voltage reference VHV. For purpose of example only, the buffer 310 is implemented as an inverter. That is, an output of the buffer 310 represents an inverse of node C, e.g. if a voltage at node C is high, an output of the inverter is low. Node C corresponds to the anode of the SPAD 305

Also depicted is a current mirror 315, configured to mirror a quench current IQ to the SPAD 305. That is, the current mirror 315 implements a passive quenching circuit configured to provide a constant quench current IQ. It will be understood that this is merely an example of a quenching circuit, and other quenching circuits are known in the art.

For example only, a representation of an output 320 from the SPAD pixel readout circuit 300 is also depicted. The buffer 310 may indicate occurrence of avalanche triggering events, e.g. photon strikes, as a drop in an output voltage of the buffer 310

The internal resistor 395 operates effectively as an internal quenching resistor.

In this example, a quenching transistor is used with the SPAD 305, e.g. in current mirror 315. Due to the effective internal quenching resistance of the conductive path, voltage requirements of any external quenching resistance may be reduced.

In the described example, requirements for any read-out electronics may also be reduced relative to the prior art SPAD pixel read-out circuit 100 of FIG. 1, according to a resistive voltage divider formed by the effective internal quenching resistor and an effective external quenching resistance of the current mirror 315.

That is, the internal quenching resistor 395 enables the SPAD 305 to be operated at an excess bias voltage exceeding a maximum operating voltage for low-voltage transistors that may be used to implement the buffer 310 and the current mirror 315. This enables the SPAD 305 to be operated with a higher excess bias voltage, thereby improving photon detection efficiency and timing jitter, and overall product performance.

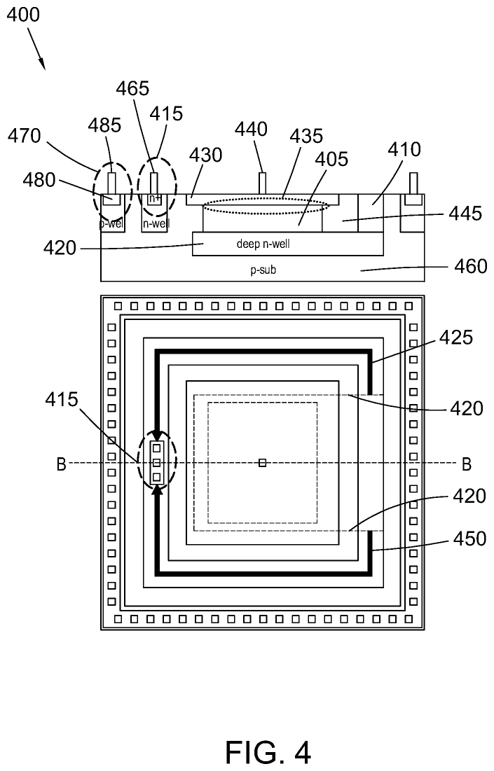

FIG. 4 depicts a plan view of a SPAD 400. FIG. 4 also depicts a cross-sectional view of the SPAD 400 across a line B-B. The SPAD 400 may be implemented as the SPAD 305 in the SPAD pixel read-out circuit 300 of FIG. 3.

Although the SPAD 400 is depicted as substantially square-shaped in plan view, it will be understood that this is for purposes of example only, and the SPAD 400 falling within the scope of the disclosure may be implemented as other shapes, such as polygonal or single-sided shapes, e.g. circular, oval-shaped, etc.

The SPAD 400 is formed on a P-type substrate 460. The example SPAD comprises a first well-region 405 formed in the substrate 460. In the following example, the first well-region 405 is denoted an “N-enhance region”, e.g. a well heavily doped with n-type impurities.

Also depicted is a second well-region 410 formed in the P-type substrate 460. The second well-region 410 is an N-type well, e.g. formed by diffusion of n-type impurities into the P-type substrate 460.

A plurality of contacts 415 are formed over a portion of the second well-region 410. The plurality of contacts 415 comprises an N+ diffused portion, for providing an ohmic contact to a plurality of cathodes 465, where the cathodes 465 may be implemented in a metal layer.

A guard ring 445 is provided by a lightly-doped lateral region extending between the first well-region 405 and the second well-region 410, and extending completely around the first well-region 405.

A deep well-region 420 is depicted. The deep well-region 420 is formed below the first well-region 405 and only a portion of the second well-region 410 in the p-type substrate 460. That is, in contrast to the SPAD 200 of FIG. 2, the deep well-region 420 extends non-uniformly between the first well-region 405 and the second well region 410, e.g. not extending continuously all around the first well region 405 as described in more detail below.

The SPAD 400 also comprises a P+ implant region 430 formed on the first well region 405, to define an avalanche region 435 of the SPAD 400.

The second well-region 410 and the deep well-region 420 are configured to provide conductive paths 425, 450 between the avalanche region 435 and the plurality of contacts 415.

A further contact 440 is formed over the implant region 430 to define an anode of the SPAD 400.

For completeness, further contacts 470 to the p-type substrate 460 are also depicted. A p-well is formed in the p-type substrate 460 and the further contacts are formed from a P+ diffused portion 480, for providing an ohmic contact to a plurality of metal contacts 485.

It can be seen in the cross-sectional view that the SPAD 400, the deep well region 420 does not extend below the plurality of contacts 415. As such, the conductive paths 425, 450 between the avalanche region 435 and the plurality of contacts 415 are indirect conductive paths 425, 450. The second well-region 410 and the deep well region 420 are not configured to provide the shortest path between the first well-region 405 and the plurality of contacts 415.

This can be seen in the plan view of the SPAD 400, e.g. in a direction orthogonal to a surface of the substrate 460, wherein it can be seen that the deep well region 420 extends only partway around the first well-region 405, and does not extend under the plurality of contacts 415. As such, the SPAD 400 effectively comprises a first conductive path 425 extending one way around the first well-region 405, and a second conductive path 450 extending the opposite way around the first well-region 405.

The deep well-region 420 extending non-uniformly between the first well-region 405 and the second well-region 410 may increase an overall resistance of the conductive paths 425, 450, compared to a resistance between the first well region 405 and the second well-region 410 of the SPAD 200 of FIG. 2. Such an increased resistance may effectively implement the above described internal quenching resistor 395, thereby enabling the SPAD 400 to be operated at an excess bias voltage exceeding a maximum operating voltage for low-voltage transistors that may be used to implement the readout circuit or quenching circuitry, e.g. buffer 310 and the current mirror 315.

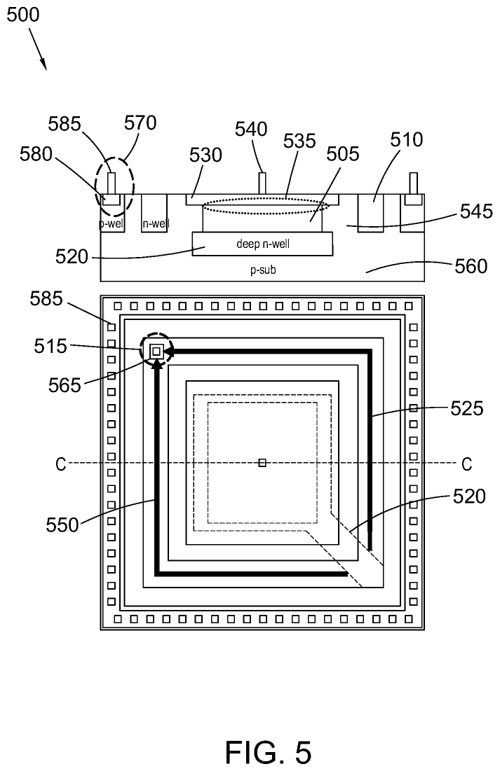

FIG. 5 depicts a plan view of a SPAD 500. FIG. 5 also depicts a cross-sectional view of the SPAD 500 across a line C-C. The SPAD 500 may be implemented as the SPAD 305 in the SPAD pixel read-out circuit 300 of FIG. 3. Although the SPAD 500 is depicted as substantially square-shaped in plan view, it will be understood that this is for purposes of example only, and the SPAD 500 falling within the scope of the disclosure may be implemented as other shapes, such as polygonal or single-sided shapes.

The SPAD 500 is formed on a P-type substrate 560. The example SPAD comprises a first well-region 505 formed in the substrate 560. In the following example, the first well-region 505 is denoted an “N-enhance region”, e.g. a well heavily doped with n-type impurities.

Also depicted is a second well-region 510 formed in the P-type substrate 560. The second well-region 510 is an N-type well, e.g. formed by diffusion of n-type impurities into the P-type substrate 560.

A single contact 515 is formed over a portion of the second well-region 510. The single contact 515 comprises an N+ diffused portion, for providing an ohmic contact to a cathode 565, where the cathode 565 may be implemented in a metal layer.

A guard ring 545 is provided by a lightly-doped lateral region extending between the first well-region 505 and the second well-region 510, and extending completely around the first well-region 505.

A deep well-region 520 is depicted. The deep well-region 520 is formed below the first well-region 505 and only a portion of the second well-region 510 in the p-type substrate 560. That is, in contrast to the SPAD 200 of FIG. 2, the deep well-region 520 extends non-uniformly between the first well-region 505 and the second well region 510, e.g. not extending continuously all around the first well region 505 as described in more detail below.

The SPAD 500 also comprises a P+ implant region 530 formed on the first well region 505, to define an avalanche region 535 of the SPAD 500.

The second well-region 510 and the deep well-region 520 are configured to provide conductive paths 525, 550 between the avalanche region 535 and the single contact 515.

By reducing a number of contacts, e.g. a single contact 515 compared to a plurality of contacts 215, a resistance of the conductive paths 525, 550 between the avalanche region 535 and the single contact 515 maybe increased relatively.

A further contact 540 is formed over the implant region 530 to define an anode of the SPAD 400.

For completeness, further contacts 570 to the p-type substrate 560 are also depicted. A p-well is formed in the p-type substrate 560 and the further contacts are formed from a P+ diffused portion 580, for providing an ohmic contact to a plurality of metal contacts 585.

It can be seen in the cross-sectional view that the SPAD 500, the deep well region 520 does not extend below the single contact 515. Relative to the embodiment of FIG. 5, only a relatively narrow portion of the deep well-region 520 extends from the first well-region 505 to the second well-region 510. By reducing a lateral width of the deep well-region 420 between the first well-region 505 and second well-region 510, an effective resistance of the conductive path may be increased without increasing an overall size of the SPAD 500. Furthermore, as can be seen in the plan view, the deep well-region 520 extends below a first corner of the second well-region 510 and the single contact 515 is provided over an opposite corner of the second well-region 510, e.g. at a furthest point from the first corner, thereby maximizing lengths of the conductive paths 525 and 550. By maximizing the lengths of the conductive paths 525 and 550, the resistance of the conductive paths 525 and 550 may also be maximized.

As such, the conductive paths 525, 550 between the avalanche region 535 and the single contact 515 are indirect conductive paths 525, 550. That is, the second well region 510 and the deep well-region 520 are not configured to provide the shortest path between the first well-region 505 and the plurality of contacts 515, and furthermore at least a deep well portion of the conductive paths 525, 550 is relatively narrow to increase its resistance.

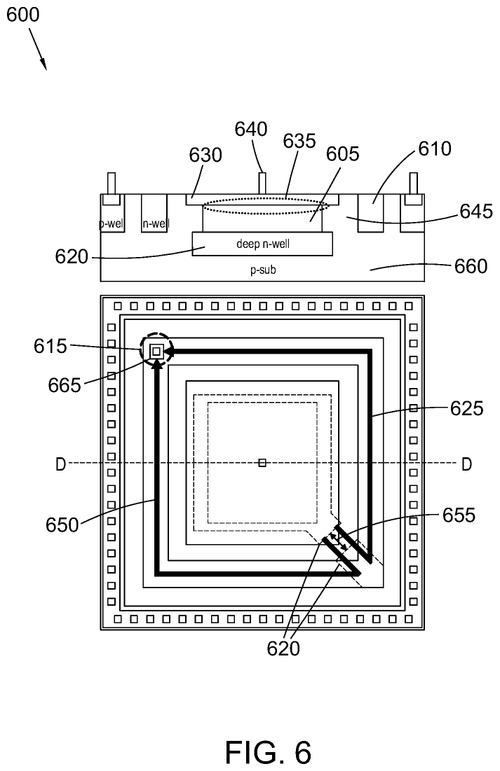

FIG. 6 depicts a plan view of a SPAD 600. FIG. 6 also depicts a cross-sectional view of the SPAD 600 across a line D-D. The SPAD 600 may be implemented as the SPAD 305 in the SPAD pixel read-out circuit 300 of FIG. 3. Although the SPAD 600 is depicted as substantially square-shaped in plan view, it will be understood that this is for purposes of example only, and the SPAD 600 falling within the scope of the disclosure may be implemented as other shapes, such as polygonal or single-sided shapes.

Most features of the SPAD 600 generally correspond to features of the SPAD 500, and therefore are not described in detail for purposes of brevity. References numerals for features of the SPAD 600 of FIG. 6 have been incremented by 100 compared to reference numerals for features of the SPAD 500 of FIG. 5. The SPAD 600 comprises: a P-type substrate 660, a first well-region 605 formed in the substrate 660; a second well-region 610 formed in the P-type substrate 660; a single contact 615 formed over a portion of the second well-region 610, wherein the single contact 615 comprises an N+ diffused portion for providing an ohmic contact to a cathode 665; a guard ring 645 provided by a lightly-doped lateral region extending between the first well-region 605 and the second well-region 610; a deep well-region 620, wherein the second well-region 610 and the deep well-region 620 are configured to provide conductive paths 625, 650 between an avalanche region 635 and the single contact 615; a P+ implant region 630 formed on the first well-region 605 to define the avalanche region 635; and a further contact 640 formed over the implant region 630 to define an anode.

The deep well-region 620 extends non-uniformly between the first well-region 605 and the second well-region 610. That is, the deep well-region 620 extends with a non-uniform doping profile.

The deep well region 620 is formed from a first portion of the deep well-region and a second portion of the deep well-region separated by a gap 655, wherein a lateral spread and/or thermal diffusion of the deep well-region 620 causes the conductive path 625, 650 to extend across the gap.

The gap 655 is effectively bridged by means of lateral spread and/or thermal diffusion, such that conductive paths 625, 650 exhibit a higher effective resistance than the paths conductive paths 525, 550 of the example SPAD 500 of FIG. 5.

A size of the gap 655 may be selected to select a resistance of the conductive path.

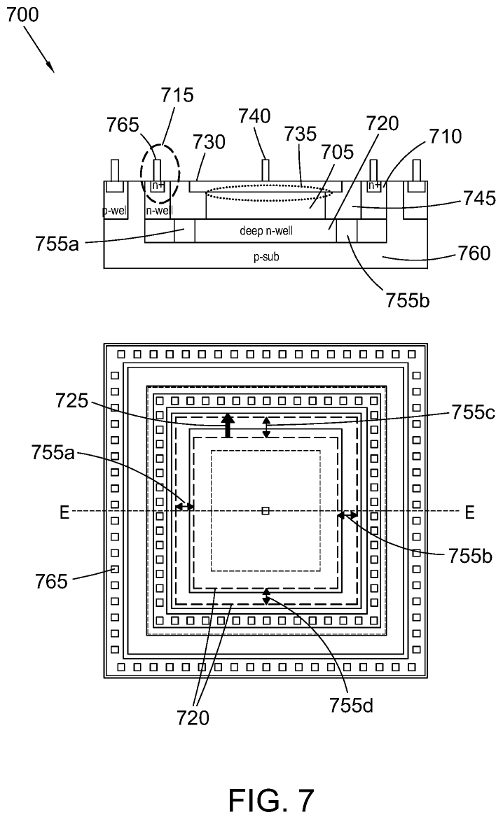

FIG. 7 depicts a plan view of a SPAD 700. FIG. 7 also depicts a cross-sectional view of the SPAD 700 across a line E-E. The SPAD 700 may be implemented as the SPAD 305 in the SPAD pixel read-out circuit 300 of FIG. 3. Although the SPAD 700 is depicted as substantially square-shaped in plan view, it will be understood that this is for purposes of example only, and the SPAD 700 falling within the scope of the disclosure may be implemented as other shapes, such as polygonal or single-sided shapes.

Most features of the SPAD 700 generally correspond to features of the SPAD 200, and therefore are not described in detail for purposes of brevity. References numerals for features of the SPAD 700 of FIG. 7 have been incremented by 500 compared to reference numerals for features of the SPAD 200 of FIG. 2. The SPAD 700 comprises: a P-type substrate 760 a first well-region 705 formed in the substrate 760; a second well-region 710 formed in the P-type substrate 760; a plurality of contacts 715 formed over the second well-region 710, wherein the plurality of contacts 715 comprises an N+ diffused portion for providing an ohmic contact to a plurality of cathodes 765; a guard ring 745 provided by a lightly-doped lateral region extending between the first well-region 705 and the second well-region 710; a deep well-region 720, wherein the second well-region 710 and the deep well-region 720 are configured to provide a conductive path between an avalanche region 735 and the plurality of contacts 715; a plurality of contacts 715; a P+ implant region 730 formed on the first well-region 705 to define the avalanche region 735; and a further contact 740 formed over the implant region 730 to define an anode.

In the example of FIG. 7, the deep well-region 620 extends non-uniformly between the first well-region 705 and the second well-region 710. That is, the deep well-region 720 extends with a non-uniform doping profile.

The deep well region 720 is formed form a first portion of the deep well-region and a second portion of the deep well-region separated by a gap 755a, 755b, 755c, 755d, wherein a lateral spread and/or thermal diffusion of the deep well-region 720 causes the conductive path to extend across the gap.

The second portion of the deep well-region 720 extends completely around the first portion of the deep well-region 720. As such, the gap 755a, 755b, 755c, 755d extends completely around the first portion of the deep well-region 720.

The gap 755a, 755b, 755c, 755d is effectively bridged by means of lateral spread and/or thermal diffusion, such that the conductive path exhibits a higher effective resistance than the conductive path of the example SPAD 200 of FIG. 2. A size of the gap 755a, 755b, 755c, 755d may be selected to select a resistance of the conductive path.

In some embodiments, the gap 755a, 755b, 755c, 755d may extend non-uniformly around the first portion of the deep well-region 720. That is, for example, one or more portions of the gap denoted 755a, 755b, 755c, 755d in FIG. 7 may be larger or smaller than at least one other portion of the gap denoted 755a, 755b, 755c, 755d in FIG. 7. As a non-limiting example, the gap denoted 755a may be larger than the gap denoted 755b. In such an embodiment, a resistance of a conductive path extending from the avalanche region 735 and across the relatively large gap denoted 755a may be higher than a resistance of a conductive path extending across the relatively small gap denoted 755a. In such an embodiment wherein the gap 755a, 755b, 755c, 755d extends non-uniformly around the first portion of the deep well-region 720, the contacts 715, e.g. the cathodes, or at least the N+ diffused portion for providing the ohmic contact, may not extend completely around the first well region. Instead, the contacts 715 may be implemented as depicted in FIG. 4, wherein the N+ diffused portion only extends only partway around the first well region 705. In such an embodiment, the contacts 715 may be only formed in the vicinity of, e.g. adjacent, the larger gap 755a, such that any conductive path extending from the avalanche region 735 extends predominantly across the smaller gap 755b, thereby increasing an overall resistance of such a conductive path. Similarly, in some embodiments having the gap 755a, 755b,

755c, 755d extending non-uniformly around the first portion of the deep well-region 720 as few as a single contact 715 may be implemented in the vicinity of, e.g. adjacent, the larger gap 755a, such as depicted in FIGS. 5 and 6.

In some embodiments having the gap 755a, 755b, 755c, 755d extending non-uniformly around the first portion of the deep well-region 720, as few as a single contact 715 may be implemented in the vicinity of the largest gap(s) and no contacts may be implemented in the vicinity of the smallest gap(s).

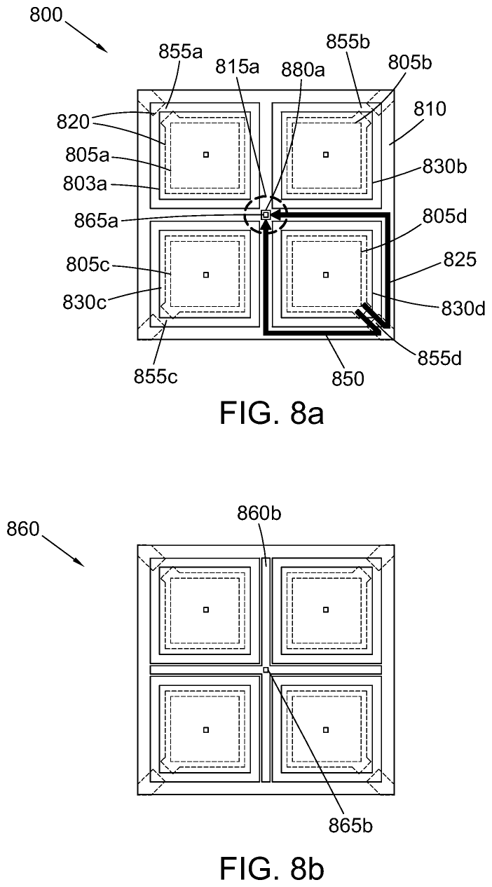

In some embodiments, one or more portions of the gap denoted 755a, 755b, 755c, 755d in FIG. 7 may be larger or smaller than at least one other portion of the gap denoted 755a, 755b, 755c, 755d in FIG. 7, and also the deep well-region 720 extends to a surface of the substrate 760. In such embodiments, the second well region 710 is effectively formed by the deep well region, e.g. a portion of the deep well region 720. In such embodiments, any conductive path extending from the avalanche region 735 to the effective second well-region, e.g. a portion of the deep well at the surface, may extend predominantly across the smaller gap(s), thereby increasing an overall resistance of such a conductive path. Further embodiments of the disclosure are depicted in FIGS. 8a and 8b, which depict arrays of SPADs 800, 860. For purposes of example only, the arrays of SPADs 800, 860 each only comprises four SPADs, although it will be appreciated that in other examples fewer than or greater than four SPADs may be implemented in each array.

FIG. 8a depicts a plan view of the SPAD array 800.

The array of SPADs comprises a plurality of first well-regions 805a, 805b, 805c, 805d formed in a substrate. A second well-region 810 is also formed on the substrate and extends around and between each of the plurality of first well-regions 805a, 805b, 805c, 805d. In the example of FIG. 8a, the second well-region 810 effectively forms a grid-like structure. A contact 815 is formed over a central portion of the second well region 810, e.g. equidistant from each first well-region 805a, 805b, 805c, 805d. The contact 815 comprises an n+ region 880a, for providing an ohmic contact to a cathode 865a.

A deep well-region 820 extends non-uniformly between each first well-region 805a, 805n, 805c, 805d and the second well-region 810, wherein the second well region and the deep well-region 820 are configured to provide conductive paths 825, 850 between avalanche regions defined by a junction with each first well-region 805a, 805b, 805c, 805d and the contact 815. For purposes of simplicity of illustration, only two conductive paths 825, 850 are illustrated for only one of the first well-regions 805d.

As described in relation to the embodiments of FIGS. 4 to 7, a P+ implant region 830a, 830b, 830c, 830d is formed on each first well-region 805a, 805b, 805c, 805d, to define the avalanche regions of four SPADs.

Similar to the embodiment of FIG. 6, the deep well region 820 is formed form first portions of the deep well-region below each first well-region 805a, 805b, 805c, 805d, and a second portions of the deep well-region extending below corners of the second well-region 810 and separated by a gaps 855a, 855b, 855c, 855d, wherein a lateral spread and/or thermal diffusion of the deep well-region 820 causes the conductive paths to extend across each gap 855a, 855b, 855c, 855d.

The deep well region 820 extends below all of the first well-regions 805a, 805b, 805c, 805d. The gaps 855 are effectively bridged by means of lateral spread and/or thermal diffusion, such that conductive paths 825, 850 exhibit a higher effective resistance than, for example, the paths conductive paths 525, 550 of the example SPAD 500 of FIG. 5. A size of each gap 855a, 855b, 855c, 855d may be selected to select a resistance of the respective conductive path.

That is, the second well-region 810 is shared between the four SPADs of the example SPAD array 800. Furthermore, the contact 815 is also shared between the four SPADs of the example SPAD array 800. This may enable the deep well-region 820 to be relatively large compared to each SPAD, and more manageably implemented within the constraints of design rules.

In the example embodiment of FIG. 8a, a majority of a voltage drop may be in the gap region, e.g. gaps 855a, 855b, 855c, 855d. As such, even if two SPADs of the four SPADs are triggered at a similar time, the remaining two SPADs may still have practically the full excess bias voltage.

Note that, for purposes of example, substrate contacts are omitted from FIGS. 8a and 8b, as each example embodiment may be a small section of a much larger array.

FIG. 8b depicts an alternative embodiment to FIG. 8a. Features of FIG. 8b generally correspond to features of FIG. 8a, and therefore are not described in further detail for purposes of brevity.

However, in contrast to the embodiment of FIG. 8a, in the example of FIG. 8b an n+ region 880b is extended between adjacent first well regions. That is, in the example of FIG. 8b, the n+ region 880b effectively forms a cruciform structure. In this example, each SPAD would see the full excess bias voltage even if the three other

SPADs are triggered. The n+ region 880b provides an ohmic contact to a single cathode 865b.

In yet further embodiments, instead of the single cathode 865b, e.g. a metal contact, in the centre, the n+ region 880b may be filled with a plurality of such metal contacts.

Although all of the above-described embodiments of the disclosure are based on a SPAD design wherein the first well-region is an N-well, and the deep well region is the only well region connecting the first well-region to the second well region, it will be appreciated that other implementations of SPADs fall within the scope of the disclosure.

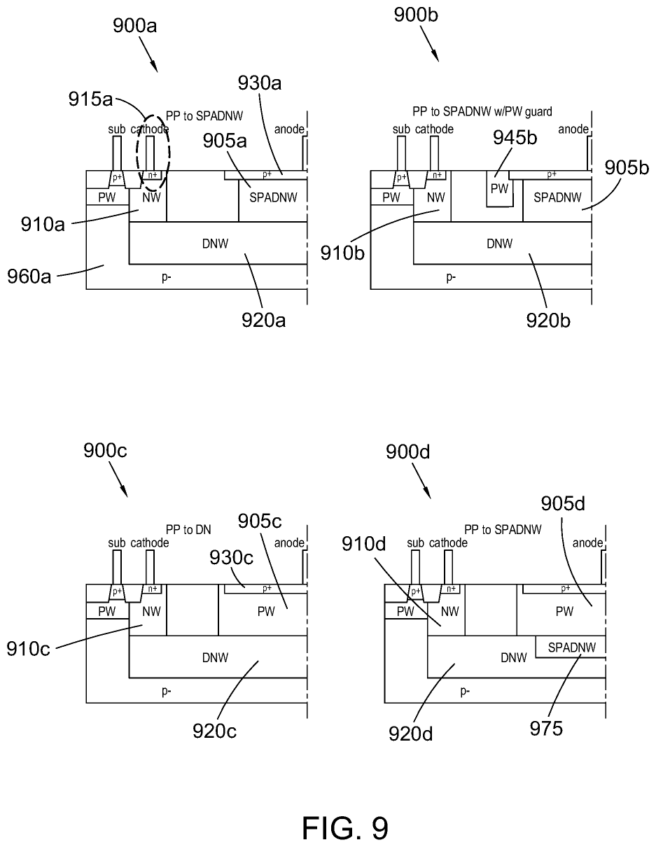

For example, FIG. 9 depicts partial cross-sections of further configurations of SPADs, which may be combined with the concepts disclosed in FIGS. 4 to 8 to implement further embodiments of the disclosure.

For example, a first SPAD configuration 900a corresponds to the SPADs of FIGS. 4 to 8, wherein: the first well-region 905a denoted “SPADNW” is an N-well formed in a P-type substrate 960a; a second well-region 910a denoted “NW” is formed on the substrate 960a as an N-well extending at least partway around the first well region 905. At least one contact 915a, is formed over the second well-region 910, and a deep well-region 920a extends non-uniformly between the first well-region 905a and the second well-region 910a. The second well-region 910a and the deep well-region 920a are configured to provide a conductive path between an avalanche region and the at least one contact 915a, wherein the avalanche region is defined by a junction between the first well-region 905a and an implant region 930a formed over the first well-region 905. As described with reference to the embodiments above, the deep well region 920a may extend non-uniformly between the first well-region 905a and the second well-region 910a by non-uniformities in a doping profile and/or implementation of one or more indirect conductive paths.

An example of a second SPAD configuration 900b generally corresponds to the first SPAD configuration 900a, with the addition of a P-well guard ring 945b formed between the first well-region 905b and the second well-region 910b.

In an example of a third SPAD configuration 900c, a first well-region 905c is implemented as a P-well, such that a PN junction providing the avalanche region of the SPAD may be formed between a deep-well region 920c and the first well-region 905c. In this example, a P+ implant region 930c is formed completely within the first well region 905.

An example of a fourth SPAD configuration 900d generally corresponds to the third SPAD configuration 900c, with the addition of a SPAD N-well 975 formed within the deep N-well and below the first well-region, such that a PN junction forming the avalanche region is formed between the SPAD N-well 975 and the first well-region 905d.

In each of first to fourth SPAD configurations 900a, 900b, 900c, 900d, and as described with reference to the embodiments above, the deep well-region 920a, 920b, 920c, 920d may extend non-uniformly between the first well-region 905a, 905b, 905c, 905d and the second well-region 910a, 910b, 910c, 910d, wherein non-uniformities are in a doping profile and/or lateral direction of one or more indirect conductive paths formed between a respective avalanche region and the respective second well-region 910a, 910b, 910c, 910d.

Although the disclosure has been described in terms of exemplary embodiments as set forth above, it should be understood that these embodiments are illustrative only and that the claims are not limited to those embodiments. Those skilled in the art will be able to make modifications and alternatives in view of the disclosure, which are contemplated as falling within the scope of the appended claims. Each feature disclosed or illustrated in the present specification may be incorporated in any embodiments, whether alone or in any appropriate combination with any other feature disclosed or illustrated herein.

### REFERENCE NUMERALS

100 SPAD pixel read-out circuit
105 SPAD
110 buffer
115 current mirror
120 output
200 SPAD
205 first well-region
210 second well-region
215 contacts
220 seep well-region
225 conductive path
230 implant region
235 avalanche region
240 further contact
260 substrate
265 cathodes
270 further contacts
280 diffused portion
285 metal contacts
300 SPAD pixel read-out circuit
305 SPAD
310 buffer
315 current mirror
320 output
395 internal resistor
400 SPAD
405 first well-region
410 second well-region
415 contact
420 deep well-region
425 conductive path
430 implant region
435 avalanche region
440 further contact
445 guard ring
450 conductive path
460 substrate
480 diffused portion
485 metal contacts
500 SPAD
505 first well-region
510 second well-region
515 contact
520 deep well-region
525 conductive path
530 implant-region
535 avalanche region
540 further contact
545 guard ring
550 conductive path
560 substrate
580 diffused portion
585 metal contacts
600 SPAD
605 first well-region
610 second well-region
615 contact
620 deep well-region
625 conductive path
630 implant region
635 avalanche region
640 further contact
645 guard ring
650 conductive path
655 gap
660 substrate
665 cathode
700 SPAD
705 first well-region
710 second well-region
715 contact
720 deep well-region
725 conductive path
730 implant region
735 avalanche region
740 further contact
745 guard ring
750 conductive path
755a gap
755b gap
755c gap
755d gap
760 substrate
800 array of SPADs
805a first well-region
805b first well-region
805c first well-region
805d first well-region
810 second well-region
815 contact
820 deep well-region
825 conductive path
830a implant region
830b implant region
830c implant region
830d implant region
850 conductive path
855a gap
855b gap
855c gap
855d gap
860 array of SPADS
865a cathode
865b cathode
880a n+ region
880b n+ region
900a first SPAD configuration
900b second SPAD configuration
900c third SPAD configuration
900d fourth SPAD configuration
905a first well-region
905b first well-region
905c first well-region
905d first well-region
910a second well-region
910b second well-region
910c second well-region
910d second well-region
915a contact
920a deep well-region
920b deep well-region
920c deep well-region
920d deep well-region
930a implant region
945b guard ring
960a substrate
970 fourth SPAD configuration
975 SPAD N-well

What is claimed is:

1. A single-photon avalanche diode, SPAD, comprising:
a first well-region formed in a substrate;
a second well-region formed on the substrate and extending at least partway around the first well-region;
at least one contact formed over the second well-region; and
a deep well-region extending non-uniformly between the first well-region and the second well-region, wherein the first well region is formed at a junction defining an avalanche region, and wherein the second well-region and the deep well-region are configured to provide a conductive path between the avalanche region and the at least one contact.

2. The SPAD of claim 1 wherein, when viewed in a direction orthogonal to a surface of the substrate, the deep well-region extends only partway around the first well-region.

3. The SPAD of claim 1, wherein a doping density of the deep well-region between the first well-region and the second well-region is non-uniform.

4. The SPAD of claim 3, wherein a region of the deep well-region between the first well-region and the second well-region has a lower doping concentration than regions of the deep well-region directly below the first well-region and the second well-region.

5. The SPAD of claim 1, wherein at least one of:
the conductive path is an indirect conductive path;
the deep well-region does not extend below the at least one contact; and/or
the second well-region and the deep well region are not configured to provide a direct conductive path between the avalanche region and the at least one contact; and/or
the conductive path is not the shortest path between the avalanche region and the at least one contact;
when viewed in a cross section extending through a center of the SPAD and through the at least one contact, the SPAD is not symmetrical.

6. The SPAD of claim 1, further comprising a plurality of conductive paths, each path extending in a different direction at least partway around the first well-region.

7. The SPAD of claim 1, further comprising an implant region formed on the first well-region to define the avalanche region of the SPAD, and at least one further contact formed over the implant region.

8. The SPAD of claim 7, wherein:
the at least one contact provides a cathode and a conductivity type of the second well-region is n-type, and the at least one further contact provides an anode and the conductivity type of the implant region is p-type; or
the at least one contact provides an anode and a conductivity type of the second well-region is p-type, and the at least one further contact provides a cathode and the conductivity type of the implant region is n-type.

9. The SPAD of claim 1, further comprising a guard ring provided by a lightly-doped lateral region extending between the first well-region and the second well-region, and extending completely around the first well-region.

10. The SPAD of claim 1, wherein, when viewed in a direction orthogonal to a surface of the substrate, the first well-region is disposed between the at least one contact and a location where the deep well-region extends to the second well-region.

11. An array of single-photon avalanche diodes (SPADs) comprising:
a plurality of first well-regions formed in a substrate;
a second well-region formed on the substrate and extending at least partway around and/or between the plurality of first well-regions;
at least one contact formed over the second well-region; and
a deep well-region extending non-uniformly between each first well-region and the second well-region, wherein each first well-region is formed at a junction defining a respective avalanche region, and wherein the second well-region and the deep well-region are configured to provide a conductive path between each avalanche region and the at least one contact.

12. A single-photon avalanche diode (SPAD) pixel read-out circuit comprising:
a SPAD according to claim 1; and
an output buffer coupled to an anode of the SPAD;
wherein the SPAD is configured such that, in use, an excess bias voltage level across an avalanche region of the SPAD exceeds a voltage level at the anode and a voltage level of a power supply the output buffer.

13. A method of manufacturing a single-photon avalanche diode (SPAD), the method comprising:
forming a deep well-region in a substrate;
forming a first well-region in the deep well-region and forming a second well-region extending at least partway around the first well-region; and
forming at least one contact over the second well region,
wherein the deep well-region is formed to extend non-uniformly between the first well-region and the second well-region, wherein the first well-region is formed at a junction defining an avalanche region, and wherein the second well-region and the deep well-region are formed to provide a conductive path between the avalanche region and the at least one contact.

14. The method of claim 13, wherein forming the deep-well region comprises forming a first portion of the deep well-region and a second portion of the deep well-region separated by a gap, wherein a lateral spread and/or thermal diffusion of the deep well-region causes the conductive path to extend across the gap.

15. The method of claim 14 wherein, when viewed the direction orthogonal to a surface of the substrate, the first portion of the deep well-region extends under the first well-region and the second portion of the deep well-region extends under the second well-region.

16. The method of claim 13, wherein the deep well-region is formed such that, when viewed in the direction orthogonal to a surface of the substrate, the deep well-region extends only partway around the first well region such that the deep well-region does not extend below the at least one contact.
